(19) United States
(12) Patent Application Publication
(10) Pub. No.: US 2024/0251189 A1
(43) Pub. Date: Jul. 25, 2024

(54) ELECTRONIC TIMING REMOTE CONTROLLER AND TIMING SETTING METHOD THEREOF

(71) Applicant: ZHENGZHOU DEWENWILS NETWORK TECHNOLOGY CO., LTD., Zhengzhou (CN)

(72) Inventor: Jinyang ZHOU, Zhengzhou (CN)

(73) Assignee: ZHENGZHOU DEWENWILS NETWORK TECHNOLOGY CO., LTD., Zhengzhou (CN)

(21) Appl. No.: 18/187,907

(22) Filed: Mar. 22, 2023

(30) Foreign Application Priority Data
Jan. 19, 2023 (CN) 202310067249.3

(51) Int. Cl. H04Q 9/02; G01R 31/371; G01R 31/3835; G06F 3/147

(52) U.S. Cl. CPC H04Q 9/02; G01R 31/371; G01R 31/3835; G06F 3/147; H04Q 2209/823

(57) ABSTRACT

Disclosed are an electronic timing remote controller and a timing setting method thereof. A user-defined timing mode, a REP timing mode, a CTD timing mode or a normally-on/normally-off timing mode is provided through key setting, so that the advantages of simple setting and convenience for operation are achieved, the learning difficulty of using products is reduced, and greater convenience is brought for the public to use. A wireless communication technology is adopted to transmit a preset information parameter of a controlled device, so that the timing remote controller can not only transmit on and off parameters, but also transmit more information according to different controlled devices, such as a bright and dark state of a dimmable lamp, a step-by-step state of opening and closing of an intelligent curtain, a temperature change state of an air conditioner or a refrigerator device, etc.

### CROSS-REFERENCE TO RELATED APPLICATIONS

This application claims priority to Chinese Patent Application No. 202310067249.3, filed on Jan. 19, 2023, the content of which is incorporated herein by reference in its entirety.

### TECHNICAL FIELD

The application relates to the technical field of electronic timing remote controllers, in particular to an electronic timing remote controller and a timing setting method thereof.

### BACKGROUND

A remote control is an apparatus used to remotely control a controlled device. An electronic timing remote controller is mainly composed of a Micro-Controller Unit (MCU) integrated circuit and a key used to generate different information (definition of information in communication studies: the information is composed of a group of interrelated meaningful symbols, which can express some complete information.) Main components include an MCU, a crystal oscillator, a memory chip, a wireless transmitting circuit and a battery voltage monitoring circuit as well as a display screen and a timing setting key. When the controlled device needs to be controlled in a certain time period, timing time may be set through the display screen and the timing setting key. When the time is up, the MCU may control the wireless communication circuit to send out a control signal to achieve the purpose of remotely controlling the controlled device.

A timing setting procedure of an electronic timer socket is generally as follows: 1. A “set” key is pressed to enter a timing mode for setting, and the screen displays “1 ON”. 2. “Hour”, “minute” and “week” are pressed, that is, the time when a first group of timing ON starts to work. The “week” key is pressed so that different week combination modes can be selected. The timer may only work in the set number of weeks as required; 3. A “set” key is pressed again, and the screen displays “1 OFF”, that is, the time when the first group of timing is turned off. For time setting, the setting method of 1 ON may be referred to. By analogy, multiple groups of ON and OFF may be set. 4. After setting, a “clock” key is pressed to return to the current time.

The existing timer remote control has the following defects that: if multiple groups do not need to be set every day, but other groups have been set, a “clear” key must be pressed to clear the time program of the redundant groups. After timing setting is completed, the “set” key is pressed to check whether the timing setting for several times is consistent with an actual situation. If there is any difference, adjustment or resetting is performed according to time needs.

### SUMMARY

The application provides an electronic timing remote controller and a timing setting method thereof. Through a multi-mode parallel or serial discrimination rule, the advantages of simple setting and convenience for operation are achieved, making the use of the electronic timing remote controller more flexible and more suitable for more scenarios.

In order to solve the above technical problem, the application provides an electronic timing remote controller, which may include a battery, a key, an MCU controller, a control circuit and a wireless communication circuit. The battery is connected with the MCU controller; the key, a Liquid Crystal Display (LCD) screen and the control circuit are all connected with the MCU controller, and the control circuit is connected with the wireless communication circuit.

The battery is configured to supply power to the MCU controller.

The MCU controller is configured to detect the state of the key, acquire current time, perform logical judgment based on the state of the key, the current time, a preset timing mode and a preset information parameter, and determine remote control information based on a logical judgment result.

The control circuit is configured to control the wireless communication circuit to send the remote control information to a corresponding controlled device, and the wireless communication circuit is also configured to receive information sent back by the controlled device.

Preferably, the battery voltage monitoring circuit, the LCD screen, a memory chip and an interface circuit are further included.

The battery voltage monitoring circuit is configured to monitor battery voltage, judge whether a low-voltage alarm is needed or not, and if so, send the low-voltage alarm to the MCU controller so as to enable the MCU controller to execute corresponding alarm operation. The alarm operation includes that: if the battery is less than 10%, the LCD screen is controlled to display a low-power icon and blink; and if the battery is less than 5%, the LCD screen is controlled to display the low-power icon and blink quickly until the battery is replaced.

The interface circuit is connected with the MCU controller, and the key is connected with the MCU controller through the interface circuit.

The LCD screen is connected with the MCU controller, and is configured to display timer time and operation state.

The memory chip is configured to store the preset timing mode and a mode parameter.

Preferably, the timing mode includes a user-defined timing mode, a Repetition (REP) timing mode, a Count down (CTD) timing mode and a normally-on/normally-off timing mode.

The user-defined timing mode is configured to set a rule and time for sending the remote control information by itself.

The REP timing mode is configured to set a cycle period to periodically send the remote control information to the controlled device according to the cycle period.

The CTD timing mode is configured to perform sampling according to a set sampling frequency and send the remote control information to the controlled device at a set time interval.

The normally-on/normally-off timing mode is configured to continuously send the remote control information to the controlled device or stop sending the remote control information to the controlled device.

Preferably, the logical judgment includes a multi-mode parallel or serial discrimination rule. The multi-mode parallel or serial discrimination rule includes the following operations.

The REP timing mode is mutually exclusive with the user-defined timing mode, the CTD timing mode and the normally-on/normally-off timing mode, and when the user-defined timing mode, the CTD timing mode or the normally-on/normally-off timing mode is activated, the REP timing mode is automatically exited.

The CTD timing mode is capable of operating parallel to the user-defined timing mode, and the user-defined timing mode and the CTD timing mode are capable of being activated at the same time.

The CTD timing mode is mutually exclusive with the REP timing mode and the normally-on/normally-off timing mode, and when the REP timing mode or the normally-on/normally-off timing mode is activated, the CTD timing mode is automatically exited.

When the CTD timing mode and the user-defined timing mode are activated at the same time, execution is performed according to the function description of the user-defined timing mode.

When the user-defined timing mode, the REP timing mode and the CTD timing mode are in an active state, the normally-on/normally-off timing mode is triggered, and the normally-on/normally-off timing mode is directly executed.

Preferably, the wireless communication circuit includes a 433 MHz wireless module, a Wi-Fi wireless communication module, a Bluetooth wireless communication module, a ZigBee wireless communication module, a 4G wireless communication module and a ZWAVE wireless communication module.

The application also provides a timing setting method of an electronic timing remote controller, which may include the following operations.

At S1, an MCU controller acquires current time and acquires a press state of a key through an interface circuit.

At S2, the MCU controller performs logical judgment based on the current time, the press state, a pre-stored timing mode and a preset information parameter, determines remote control information based on a logical judgment result, and sends the remote control information to a corresponding controlled device.

Preferably, in S1, the operation that the MCU controller acquires the current time further includes the following operation.

The current time is updated/set, the updated/set current time is sent to the MCU controller for storage, and the MCU controller displays a time value on an LCD screen based on the current time.

Preferably, after the MCU controller displays the time value on the LCD screen based on the current time, the following operations are further included.

The timing mode and the preset information parameter of the controlled device are determined based on a key signal of the key to determine a one-way socket needing timing setting, the timing mode is set as a user-defined timing mode, a repetition REP timing mode, a countdown CTD timing mode or a normally-on/normally-off timing mode based on a multi-mode parallel or serial discrimination rule, and the timing mode and the preset information parameter of the controlled device are sent to the MCU controller and stored to a memory chip. The preset information parameter includes timing time, an on/off state of the controlled device and an adjustable state of the controlled device. The adjustable state of the controlled device includes a bright and dark state of a lamp, a step-by-step state of opening and closing of an intelligent curtain, and a temperature change state of an air conditioner or a refrigerator device.

Preferably, the multi-mode parallel or serial discrimination rule includes the following operations.

The REP timing mode is mutually exclusive with the user-defined timing mode, the CTD timing mode and the normally-on/normally-off timing mode, and when the user-defined timing mode, the CTD timing mode or the normally-on/normally-off timing mode is activated, the REP timing mode is automatically exited.

The CTD timing mode is capable of operating parallel to the user-defined timing mode, and the user-defined timing mode and the CTD timing mode are capable of being activated at the same time.

The CTD timing mode is mutually exclusive with the REP timing mode and the normally-on/normally-off timing mode, and when the REP timing mode or the normally-on/normally-off timing mode is activated, the CTD timing mode is automatically exited.

When the CTD timing mode and the user-defined timing mode are activated at the same time, execution is performed according to the function description of the user-defined timing mode.

When the user-defined timing mode, the REP timing mode and the CTD timing mode are in an active state, the normally-on/normally-off timing mode is triggered, and the normally-on/normally-off timing mode is directly executed.

Preferably, S2 specifically includes the following operations.

At S21, the MCU controller acquires the timing mode and the preset information parameter of the controlled device from the memory chip through the relay control circuit.

At S22, the MCU controller monitors battery voltage through the battery voltage monitoring circuit, judges whether a low-voltage alarm is needed or not, and if so, sends the low-voltage alarm to the MCU controller so as to enable the MCU controller to execute corresponding alarm operation. The alarm operation includes that: if the battery is less than 10%, the LCD screen is controlled to display a low-power icon and blink; and if the battery is less than 5%, the LCD screen is controlled to display the low-power icon and blink quickly until the battery is replaced.

At S23, the MCU controller performs logical judgment on the timing mode, the current time and the preset information parameter, if the current time reaches the timing time, proceeding to S24, otherwise returning to S21.

At S24, the MCU controller enables the control circuit to send the remote control information to the corresponding controlled device through the control circuit.

The application provides an electronic timing remote controller and a timing setting method thereof. The user-defined timing mode, the REP timing mode, the CTD timing mode or the normally-on/normally-off timing mode is provided through key setting, so that the advantages of simple setting and convenience for operation are achieved, the learning difficulty of using products is reduced, and greater convenience is brought for the public to use. A wireless communication technology is adopted to transmit the preset information parameter of the controlled device, so that the timing remote controller can not only transmit on and off parameters, but also transmit more information according to different controlled devices, such as the bright and dark state of the dimmable lamp, the step-by-step state of opening and closing of the intelligent curtain, the temperature change state of the air conditioner or the refrigerator device, etc., which greatly expands the application scope of the timing remote controller.

### BRIEF DESCRIPTION OF THE DRAWINGS

In order to more clearly explain the technical solutions in the embodiments of the application or in a traditional art, the drawings required in the descriptions of the embodiments or the traditional art will be briefly introduced below. It is apparent that the drawings in the following descriptions are some embodiments of the application. Those of ordinary skill in the art may also obtain other drawings in accordance with these drawings without paying creative labor.

FIG. 1 is a schematic structural diagram of an electronic timing remote controller according to an embodiment of the application.

FIG. 2 is a flowchart of a timing setting method according to an embodiment of the application.

FIG. 3 is the specific flow diagram in FIG. 2 of the application.

FIG. 4 is the specific flow diagram of step S1 of the application.

FIG. 5 is the specific flow diagram of step S2 of the application.

### DETAILED DESCRIPTION OF THE EMBODIMENTS

In order to make the purposes, technical solutions and advantages of the embodiments of the application clearer, the technical solutions in the embodiments of the application will be clearly and completely described below in combination with the drawings in the embodiments of the application, and it is apparent that the described embodiments are only a part rather all of embodiments of the application. All other embodiments obtained by those of ordinary skill in the art on the basis of the embodiments in the application without creative work shall fall within the scope of protection of the application.

The term “and/or” in the embodiments of the application describes only an association relationship for describing associated objects and represents that three relationships may exist. For example, A and/or B may represent the following three cases: Only A exists, both A and B exist, or only B exists.

Terms “first” and “second” in the embodiments of the application are only used for describing purposes, and cannot be understood as indicating or implying relative importance or implicitly indicating the number of indicated technical features. Therefore, the features defined with “first” and “second” may include at least one of the features explicitly or implicitly. In the description of the application, terms “include” and “have” and any variations thereof are intended to cover non-exclusive inclusion. For example, a system, product or device including a series of components or units is not limited to the components or units which are listed, but may alternatively further include components or units which are not listed or alternatively further include other components or units intrinsic to the product or device. In the descriptions of the application, “multiple” means at least two, for example, two and three, unless otherwise limited definitely and specifically.

Reference to an “embodiment” herein means that a particular feature, structure or characteristic described in connection with an embodiment may be included in at least one embodiment of the application. The appearance of this phrase in various places in the specification does not necessarily mean the same embodiment, nor is it an independent or alternative embodiment mutually exclusive with other embodiments. Those skilled in the art understand explicitly and implicitly that the embodiments described herein may be combined with other embodiments.

An existing timer remote control has the following defects that: if multiple groups do not need to be set every day, but other groups have been set, a “clear” key must be pressed to clear the time program of the redundant groups. After timing setting is completed, a “set” key is pressed to check whether the timing setting for several times is consistent with an actual situation. If there is any difference, adjustment or resetting is performed according to time needs.

Therefore, the embodiments of the application provide an electronic timing remote controller and a timing setting method thereof. A user-defined timing mode, a REP timing mode, a CTD timing mode or a normally-on/normally-off timing mode is provided through key setting, so that the advantages of simple setting and convenience for operation are achieved, the learning difficulty of using products is reduced, and greater convenience is brought for the public to use. The electronic timing remote controller and the timing setting method according to the embodiments of the application are described below with reference to the accompanying drawings.

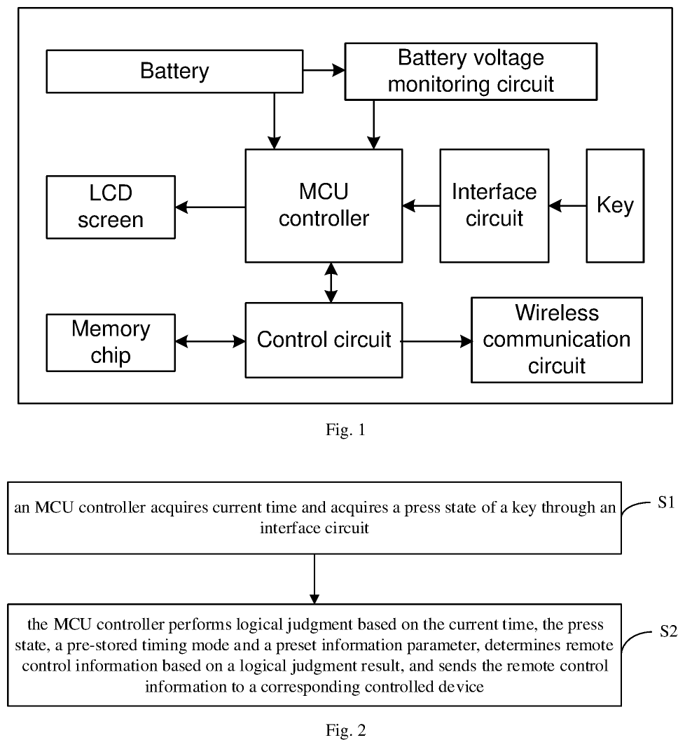

FIG. 1 and FIG. 2 are an electronic timing remote controller provided according to the embodiments of the application, including a battery, a key, an MCU controller, a control circuit and a wireless communication circuit. The battery is connected with the MCU controller; the key, an LCD screen and the control circuit are all connected with the MCU controller; and the control circuit is connected with the wireless communication circuit.

The key is connected with the MCU controller and configured to set a timing mode and adjust a timer time parameter and a preset information parameter of a controlled device.

The battery is configured to supply power to the MCU controller.

The MCU controller is configured to detect the state of the key, perform logical judgment and complete the control over the wireless communication circuit, perform logical judgment by detecting the state of the key and acquiring current time and based on the state of the key, the current time, the preset timing mode and the preset information parameter, and determine remote control information based on a logical judgment result.

The control circuit is configured to send the remote control information to the corresponding controlled device, and the control circuit is also configured to receive information sent back by the controlled device. The wireless communication circuit includes a 433 MHz wireless module, a Wi-Fi wireless communication module, a Bluetooth wireless communication module, a ZigBee wireless communication module, a 4G wireless communication module and a ZWAVE wireless communication module.

A battery voltage monitoring circuit, the LCD screen, a memory chip and an interface circuit are further included. A crystal oscillator, a peripheral circuit and a casing are further included. The above-mentioned components are connected according to electrical characteristics and structural features.

The battery voltage monitoring circuit is configured to monitor battery voltage, judge whether a low-voltage alarm is needed or not, and if so, send the low-voltage alarm to the MCU controller so as to enable the MCU controller to execute corresponding alarm operation. The alarm operation includes that: if the battery is less than 10%, the LCD screen is controlled to display a low-power icon and blink; and if the battery is less than 5%, the LCD screen is controlled to display the low-power icon and blink quickly until the battery is replaced.

The interface circuit is connected with the MCU controller, and the key is connected with the MCU controller through the interface circuit.

The LCD screen is connected with the MCU controller, and is configured to display timer time and operation state.

The memory chip is configured to store the preset timing mode and a mode parameter.

Based on the above embodiment, as a preferred implementation mode, the timing mode includes a user-defined timing mode, a REP timing mode, a CTD timing mode and a normally-on/normally-off timing mode.

The user-defined timing mode is configured to set a rule and time for sending the remote control information by itself.

The REP timing mode is configured to set a cycle period to periodically send the remote control information to the controlled device according to the cycle period.

The CTD timing mode is configured to perform sampling according to a set sampling frequency and send the remote control information to the controlled device at a set time interval.

The normally-on/normally-off timing mode is configured to continuously send the remote control information to the controlled device or stop sending the remote control information to the controlled device.

Based on the above embodiment, as a preferred implementation mode, the logical judgment includes a multi-mode parallel or serial discrimination rule. The multi-mode parallel or serial discrimination rule includes the following operations.

The REP timing mode is mutually exclusive with the user-defined timing mode, the CTD timing mode and the normally-on/normally-off timing mode, and when the user-defined timing mode, the CTD timing mode or the normally-on/normally-off timing mode is activated, the REP timing mode is automatically exited.

The CTD timing mode is capable of operating parallel to the user-defined timing mode, and the user-defined timing mode and the CTD timing mode are capable of being activated at the same time.

The CTD timing mode is mutually exclusive with the REP timing mode and the normally-on/normally-off timing mode, and when the REP timing mode or the normally-on/normally-off timing mode is activated, the CTD timing mode is automatically exited.

When the CTD timing mode and the user-defined timing mode are activated at the same time, execution is performed according to the function description of the user-defined timing mode.

When the user-defined timing mode, the REP timing mode and the CTD timing mode are in an active state, the normally-on/normally-off timing mode is triggered, and the normally-on/normally-off timing mode is directly executed.

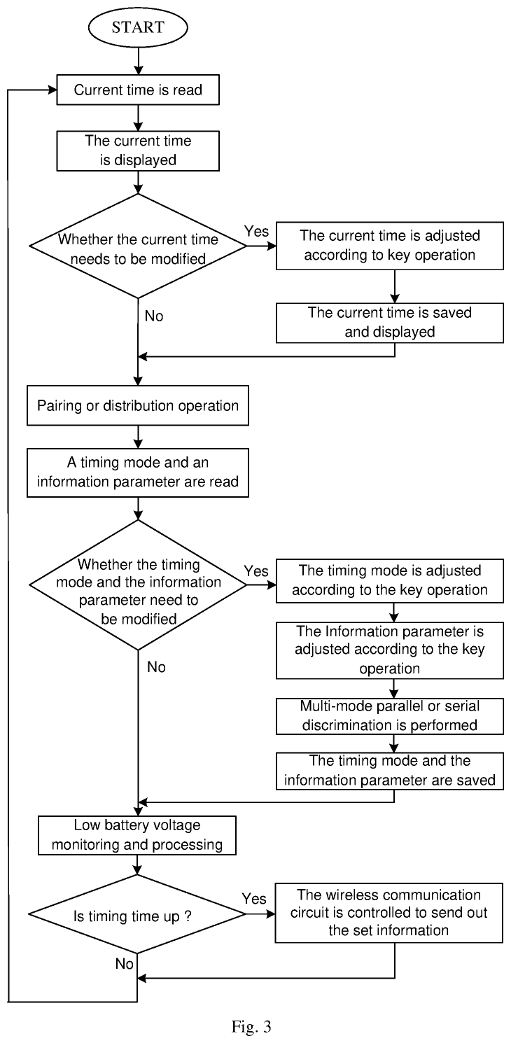

The embodiment of the application further provides a timing setting method of the electronic timing remote controller according to the above-mentioned embodiment. The timing setting method may also be applied to the above electronic timing remote controller. As shown in FIG. 2 and FIG. 3, the timing setting method includes the following operations.

At S1, an MCU controller acquires current time and acquires a press state of a key through an interface circuit; the MCU controller acquires the current time and displays same through an LCD screen, the MCU controller detects the state of the key through the interface circuit, and the MCU controller acquires a timing mode from a memory chip through a control circuit and displays same through the LCD screen.

At S2, the MCU controller performs logical judgment based on the current time, the press state, the pre-stored timing mode and a preset information parameter, determines remote control information based on a logical judgment result, and sends the remote control information to a corresponding controlled device.

Based on the above-mentioned embodiment, as a preferred implementation mode, in S1, the operation that the MCU controller acquires the current time further includes the following operation.

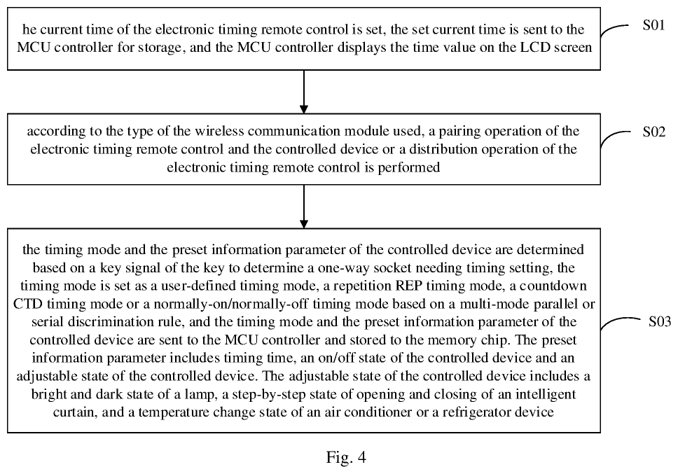

The current time is updated/set, the updated/set current time is sent to the MCU controller for storage, and the MCU controller displays a time value on the LCD screen based on the current time. The current time of the electronic timing remote controller is read, whether it is necessary to modify the current time is judged, and if so, the current time of the electronic timing remote controller is set with the key. As shown in FIG. 4, The following operations are specifically included.

At S01, the current time of the electronic timing remote controller is set, the set current time is sent to the MCU controller for storage, and the MCU controller displays the time value on the LCD screen.

At S02, according to the type of the wireless communication module used, a pairing operation of the electronic timing remote controller and the controlled device or a distribution operation of the electronic timing remote controller is performed.

At S03, the timing mode and the preset information parameter of the controlled device are determined based on a key signal of the key to determine a one-way socket needing timing setting, the timing mode is set as a user-defined timing mode, a REP timing mode, a CTD timing mode or a normally-on/normally-off timing mode based on a multi-mode parallel or serial discrimination rule, and the timing mode and the preset information parameter of the controlled device are sent to the MCU controller and stored to the memory chip. The preset information parameter includes timing time, an on/off state of the controlled device and an adjustable state of the controlled device. The adjustable state of the controlled device includes a bright and dark state of a lamp, a step-by-step state of opening and closing of an intelligent curtain, and a temperature change state of an air conditioner or a refrigerator device.

Based on the above embodiment, as a preferred implementation mode, the multi-mode parallel or serial discrimination rule includes the following operations.

The REP timing mode is mutually exclusive with the user-defined timing mode, the CTD timing mode and the normally-on/normally-off timing mode, and when the user-defined timing mode, the CTD timing mode or the normally-on/normally-off timing mode is activated, the REP timing mode is automatically exited.

The CTD timing mode is capable of operating parallel to the user-defined timing mode, and the user-defined timing mode and the CTD timing mode are capable of being activated at the same time.

The CTD timing mode is mutually exclusive with the REP timing mode and the normally-on/normally-off timing mode, and when the REP timing mode or the normally-on/normally-off timing mode is activated, the CTD timing mode is automatically exited.

When the CTD timing mode and the user-defined timing mode are activated at the same time, execution is performed according to the function description of the user-defined timing mode.

When the user-defined timing mode, the repetition REP timing mode and the countdown CTD timing mode are in an active state, the normally-on/normally-off timing mode is triggered, and the normally-on/normally-off timing mode is directly executed.

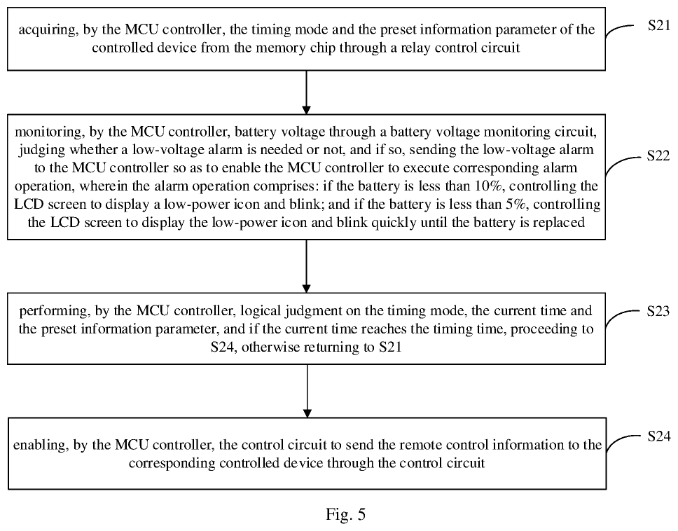

Based on the above-mentioned embodiment, as a preferred implementation mode, As shown in FIG. 5, S2 specifically includes the following operations.

At S21, the MCU controller acquires the timing mode and the preset information parameter of the controlled device from the memory chip through the relay control circuit.

At S22, the MCU controller monitors battery voltage through the battery voltage monitoring circuit, judges whether a low-voltage alarm is needed or not, and if so, sends the low-voltage alarm to the MCU controller so as to enable the MCU controller to execute corresponding alarm operation. The alarm operation includes that: if the battery is less than 10%, the LCD screen is controlled to display a low-power icon and blink; and if the battery is less than 5%, the LCD screen is controlled to display the low-power icon and blink quickly until the battery is replaced.

At S23, the MCU controller performs logical judgment on the timing mode, the current time and the preset information parameter, if the current time reaches the timing time, proceeding to S24, otherwise returning to S21.

At S24, the MCU controller enables the control circuit to send the remote control information to the corresponding controlled device through the control circuit.

Based on all the above embodiments, a specific application embodiment is also provided. In the embodiment, the electronic timing remote controller in the embodiment of the application is used to control the timing switch of a 433 MHz power switch socket. First, a touch switch is pressed to set the current time, the electronic timing remote controller is paired with the 433 MHz power switch socket, and then the REP timing function of the electronic timing remote controller is turned on. The touch switch is set to send out a remote control signal of turning on the 433 MHz power switch socket at 8:00 every morning and a remote control signal of turning off the 433 MHz power switch socket at 19:00 every day.

At this time, the electronic timing remote controller starts to work, and the current time is always refreshed. When the time is refreshed to 8:00 in the morning, the remote control signal of turning on the 433 MHz power switch socket is sent out to turn on the 433 MHz power switch socket, and when the time is refreshed to 19:00, the remote control signal of turning off the 433 MHz power switch socket is sent out to turn off the 433 MHz power switch socket.

It is to be seen from the above specific application examples, the electronic timing remote controller in the application has the advantages of simple setting and convenience for operation by setting daily repetition timing.

In conclusion, the embodiments of the application provide an electronic timing remote controller and a timing setting method thereof. The user-defined timing mode, the REP timing mode, the CTD timing mode or the normally-on/normally-off timing mode is provided through key setting, so that the advantages of simple setting and convenience for operation are achieved, the learning difficulty of using products is reduced, and greater convenience is brought for the public to use. The wireless communication technology is adopted to transmit the preset information parameter of the controlled device, so that the timing remote controller can not only transmit on and off parameters, but also transmit more information according to different controlled devices, such as the bright and dark state of the dimmable lamp, the step-by-step state of opening and closing of the intelligent curtain, the temperature change state of the air conditioner or the refrigerator device, etc., which greatly expands the application scope of the timing remote controller.

The embodiments may be implemented completely or partially through software, hardware, firmware or any combination thereof. During implementation with the software, the embodiments may be implemented completely or partially in form of a computer program product. The computer program product includes one or more computer instructions. When the computer program instruction is loaded and executed on a computer, the flows or functions according to the application are completely or partially generated. The computer may be a universal computer, a dedicated computer, a computer network, or another programmable device. The computer instructions may be stored in a computer-readable storage medium or transmitted from one computer-readable storage medium to another computer-readable storage medium. For example, the computer instructions may be transmitted from one website, computer, server or data center to another website, computer, server or data center in a wired (for example, coaxial cable, optical fiber and Digital Subscriber Line (DSL) or wireless (for example, infrared, wireless and microwave) manner. The computer-readable storage medium may be any available medium accessible for the computer or data storage equipment including one or more integrated available media such as a server and a data center. The available medium may be a magnetic medium (for example, a floppy disk, a hard disk and a magnetic tape), an optical medium (for example, a Digital Versatile Disc (DVD), a semiconductor medium (for example, a Solid State Disk (SSD)) or the like.

Those of ordinary skill in the art may understand that implementation of all or part of the processes in the above embodiment method may be completed by instructing related hardware through a computer program, and the program may be stored in a computer-readable storage medium. The program, when executed, may include the processes of the embodiments of the above methods. The foregoing storage medium includes various media that can store program codes, such as a Read Only Memory (ROM), a RAM, a magnetic disk or an optical disc.

The last thing to be noted is: the above embodiments are only used to illustrate the technical solutions of the application and not used to limit the same. Although the application has been described in detail with reference to the foregoing embodiments, for those skilled in the art, they can still modify the technical solutions described in the foregoing embodiments, or equivalently replace part of the technical features; all these modifications and replacements shall not cause the essence of the corresponding technical solutions to depart from the spirit and scope of protection of the application.

What is claimed is:

1. An electronic timing remote controller, comprising a battery, a key, a controller, a control circuit and a wireless communication circuit,
wherein the battery is connected with a Micro-Controller Unit (MCU) controller, the key, a Liquid Crystal Display (LCD) screen and the control circuit are all connected with the MCU controller, and the control circuit is connected with the wireless communication circuit;
the battery is configured to supply power to the MCU controller, the MCU controller is configured to detect the state of the key, acquire current time, perform logical judgment based on the state of the key, the current time, a preset timing mode and a preset information parameter, and determine remote control information based on a logical judgment result; and
the control circuit is configured to control the wireless communication circuit to send the remote control information to a corresponding controlled device, and the wireless communication circuit is also configured to receive information sent back by the controlled device.

2. The electronic timing remote controller according to claim 1, further comprising a battery voltage monitoring circuit, the LCD screen, a memory chip and an interface circuit,
wherein the battery voltage monitoring circuit is configured to monitor battery voltage, judge whether a low-voltage alarm is needed or not, and if so, send the low-voltage alarm to the MCU controller so as to enable the MCU controller to execute corresponding alarm operation,
wherein the alarm operation comprises: if the battery is less than 10%, controlling the LCD screen to display a low-power icon and blink; and if the battery is less than 5%, controlling the LCD screen to display the low-power icon and blink quickly until the battery is replaced;
the interface circuit is connected with the MCU controller, and the key is connected with the MCU controller through the interface circuit;
the LCD screen is connected with the MCU controller, and is configured to display timer time and operation state; and
the memory chip is configured to store the preset timing mode and a mode parameter.

3. The electronic timing remote controller according to claim 2, wherein the timing mode comprises one or more of the following modes: a user-defined timing mode, a REP timing mode, a CTD timing mode or a normally-on/normally-off timing mode,
the user-defined timing mode is configured to set a rule and time for sending the remote control information by itself;
the REP timing mode is configured to set a cycle period to periodically send the remote control information to the controlled device according to the cycle period;
the CTD timing mode is configured to perform sampling according to a set sampling frequency and send the remote control information to the controlled device at a set time interval; and
the normally-on/normally-off timing mode is configured to continuously send the remote control information to the controlled device or stop sending the remote control information to the controlled device.

4. The electronic timing remote controller according to claim 3, wherein the logical judgment comprises a multi-mode parallel or serial discrimination rule, the multi-mode parallel or serial discrimination rule comprises:
the REP timing mode being mutually exclusive with the user-defined timing mode, the CTD timing mode and the normally-on/normally-off timing mode, and when the user-defined timing mode, the CTD timing mode or the normally-on/normally-off timing mode is activated, the REP timing mode being automatically exited;
the CTD timing mode being capable of operating parallel to the user-defined timing mode, and the user-defined timing mode and the CTD timing mode being capable of being activated at the same time;
the CTD timing mode being mutually exclusive with the REP timing mode and the normally-on/normally-off timing mode, and when the REP timing mode or the normally-on/normally-off timing mode is activated, the CTD timing mode being automatically exited;
when the CTD timing mode and the user-defined timing mode are activated at the same time, execution being performed according to the function description of the user-defined timing mode; and
when the user-defined timing mode, the repetition REP timing mode and the countdown CTD timing mode are in an active state, the normally-on/normally-off timing mode being triggered, and the normally-on/normally-off timing mode being directly executed.

5. The electronic timing remote controller according to claim 1, wherein the wireless communication circuit comprises one or more of the following modules: a 433 MHz wireless module, a Wi-Fi wireless communication module, a Bluetooth wireless communication module, a ZigBee wireless communication module, a 4G wireless communication module or a ZWAVE wireless communication module.

6. A timing setting method of the electronic timing remote controller according to claim 1, comprising:
S1: acquiring, by a Micro-Controller Unit (MCU) controller, current time and acquiring a press state of a key through an interface circuit; and
S2: performing, by the MCU controller, logical judgment based on the current time, the press state, a pre-stored timing mode and a preset information parameter, determining remote control information based on a logical judgment result, and sending the remote control information to a corresponding controlled device.

7. The timing setting method of the electronic timing remote controller according to claim 6, wherein in S1, acquiring, by the MCU controller, the current time further comprises:
updating/setting the current time, sending the updated/set current time to the MCU controller for storage, and displaying, by the MCU controller, a time value on an LCD screen based on the current time.

8. The timing setting method of the electronic timing remote controller according to claim 6, after displaying, by the MCU controller, the time value on the LCD screen based on the current time, further comprising:
determining the timing mode and the preset information parameter of the controlled device based on a key signal of the key to determine a one-way socket needing timing setting;
setting the timing mode as a user-defined timing mode, a REP timing mode, a CTD timing mode or a normally-on/normally-off timing mode based on a multi-mode parallel or serial discrimination rule;
sending the timing mode and the preset information parameter of the controlled device to the MCU controller and storing same to a memory chip;
the preset information parameter comprising timing time, an on/off state of the controlled device and an adjustable state of the controlled device, and the adjustable state of the controlled device comprising a bright and dark state of a lamp, a step-by-step state of opening and closing of an intelligent curtain, and a temperature change state of an air conditioner or a refrigerator device.

9. The timing setting method of the electronic timing remote controller according to claim 8, wherein the multi-mode parallel or serial discrimination rule comprises:
the REP timing mode being mutually exclusive with the user-defined timing mode, the CTD timing mode and the normally-on/normally-off timing mode, and when the user-defined timing mode, the CTD timing mode or the normally-on/normally-off timing mode is activated, the REP timing mode being automatically exited;
the CTD timing mode being capable of operating parallel to the user-defined timing mode, and the user-defined timing mode and the CTD timing mode being capable of being activated at the same time;
the CTD timing mode being mutually exclusive with the REP timing mode and the normally-on/normally-off timing mode, and when the REP timing mode or the normally-on/normally-off timing mode is activated, the CTD timing mode being automatically exited;
when the CTD timing mode and the user-defined timing mode are activated at the same time, execution being performed according to the function description of the user-defined timing mode; and
when the user-defined timing mode, the REP timing mode and the CTD timing mode are in an active state, the normally-on/normally-off timing mode being triggered, and the normally-on/normally-off timing mode being directly executed.

10. The timing setting method of the electronic timing remote controller according to claim 8, wherein S2 specifically comprises:
S21: acquiring, by the MCU controller, the timing mode and the preset information parameter of the controlled device from the memory chip through a relay control circuit;
S22: monitoring, by the MCU controller, battery voltage through a battery voltage monitoring circuit, judging whether a low-voltage alarm is needed or not, and if so, sending the low-voltage alarm to the MCU controller so as to enable the MCU controller to execute corresponding alarm operation, wherein the alarm operation comprises: if the battery is less than 10%, controlling the LCD screen to display a low-power icon and blink; and if the battery is less than 5%, controlling the LCD screen to display the low-power icon and blink quickly until the battery is replaced;
S23: performing, by the MCU controller, logical judgment on the timing mode, the current time and the preset information parameter, and if the current time reaches the timing time, proceeding to S24, otherwise returning to S21; and
S24: enabling, by the MCU controller, the control circuit to send the remote control information to the corresponding controlled device through the control circuit.
